(19) United States
(12) Patent Application Publication
(10) Pub. No.: US 2003/0071269 A1
(43) Pub. Date: Apr. 17, 2003

(54) Apparatus and method for laser selective bonding technique for making sealed or enclosed microchannel structures

(76) Inventor: Ampere A. Tseng, Phoenix, AZ (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/271,307

(22) Filed: Oct. 15, 2002

Related U.S. Application Data
(60) Provisional application No. 60/329,450, filed on Oct. 15, 2001.

(51) Int. Cl. H01L 33/00; G02C 7/00; H01L 21/30

(52) U.S. Cl. 257/98; 257/731; 156/99; 438/455

(57) ABSTRACT

A method and apparatus for making sealed or closed microchannel structures in semiconductor wafers is disclosed. Two substrates, preferably a transparent cover substrate and an opaque base substrate, are used. The transparent cover substrate is placed over the opaque base substrate. By using the characteristics of the transparent material, electromagnetic waves are directed through the transparent cover substrate to the opaque base substrate. The laser beam heats the base substrate to its phase change temperature, melting the surface of the base substrate that is in contact with a surface of the cover substrate, coalescing the surfaces together and forming a sealed microchannel structure.

### CLAIM TO DOMESTIC PRIORITY

The present non-provisional patent application claims priority to provisional application serial No. 60/329,450, entitled “Laser Selective Bonding Technique for Making Sealed or Enclosed Microchannel Structures,” filed on Oct. 15, 2001, by Ampere A. Tseng.

### FIELD OF THE INVENTION

The present invention relates generally to an apparatus and method for fabricating micrometer and nanometer semiconductor scale devices, and more specifically, to an apparatus and method using electromagnetic waves to selectively bond a cover substrate onto a base substrate by making closed or sealed microchannels.

### BACKGROUND OF THE INVENTION

Semiconductor manufacturers make integrated circuit chips on what is usually referred to as wafers or semiconductor wafers. These wafers are generally flat disks, currently between 100 to 300 mm in diameter and may contain up to several thousand dies, each representing an integrated circuit chip. The fabrication of micrometer and nanometer scale devices used in the semiconductor industry normally involves the use of lithography (including etching and deposition) and packaging (including bonding and assembly). Both these processes are costly, have resolution limitations, and are slow in their throughput.

Additionally, in many microelectromechanical systems, microchannel structures, including trenches, cavities and connector holes, have been widely used as connectors between pumps, valves, and sensors. Microchannel structures are also used as separation columns for heat exchangers, microreactors, and chromatography. In these micro-fluidic applications, microchannel structures need to be sealed.

Existing sealing techniques have been primarily developed for the semiconductor industry. Normally, closed or sealed microchannels are formed using wafer-to-wafer bonding techniques which bond a cover substrate onto a machined substrate to form a closed or sealed microchannel. The wafer-to-wafer conventional bonding technique normally creates sealed microchannels by contacting and bonding the entire area when the bonding is only required in specifically selected areas.

Such techniques used include fusion bonding, anodic bonding, and eutectic bonding. These techniques have several disadvantages. In order to perform these existing bonding techniques, special conditions are normally required. To perform fusion, anodic, or eutectic bonding, relative high temperatures, normally greater than 800° C. are required. Fusion and anodic bonding normally require a surface roughness of about 4 nm for fusion bonding and about 1 μm for anodic bonding.

Vacuum conditions are often required for existing bonding techniques, increasing the cost of manufacturing. Existing bonding techniques are also normally performed at a later stage in production of the semiconductor wafers. At this stage, the cover layer and the machined layer normally must be realigned accurately, also increasing the cost of manufacturing.

Therefore, a need exists for an apparatus and method of making sealed or enclosed microchannels that can selectively bond the cover substrate to the machined substrate while reducing cost of manufacture.

### BRIEF DESCRIPTION OF THE DRAWINGS

FIG. 1 is a side view of one embodiment of an apparatus in which the method can be practiced;

FIG. 2 is an alternate embodiment of the apparatus;

FIG. 3 is a cross-sectional illustration of substrates used in one embodiment of the apparatus;

FIG. 4 is a cross-sectional illustration of electromagnetic waves directed through the cover substrate of one embodiment;

FIG. 5 is a cross-sectional illustration of one embodiment of the method of making a sealed microchannel structure;

FIG. 6 is a cross-sectional illustration of one embodiment of a sealed microchannel structure;

FIG. 7 is a micrograph cross-section of one embodiment of a silicon-to glass bond created by the laser selective bonding method;

FIG. 8 is a three-dimensional illustration of one embodiment of a sealed microchannel structure; and

FIG. 9 is an illustration of alternate embodiments of selective substrate bonding methods.

### DETAILED DESCRIPTION OF VARIOUS EMBODIMENTS

This description discloses an apparatus and method for selectively bonding two substrates by making sealed or enclosed microchannel structures using a laser.

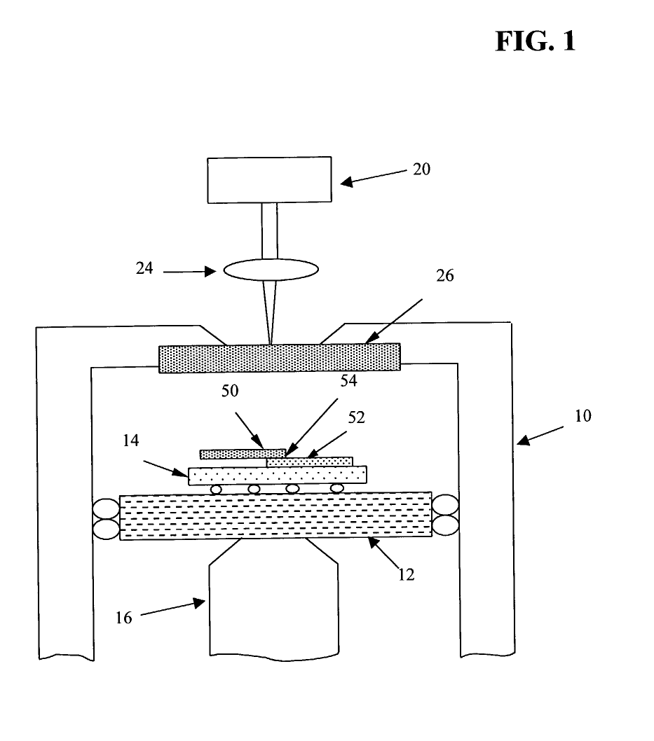

FIG. 1 illustrates a general overview of one embodiment of an apparatus used for laser selective bonding. In FIG. 1, a precision vibration-free table 10 is shown. Platform 12 is held in place by precision vibration-free table 10. In one embodiment platform 12 is a linear induction motor table. XY stage 14 is located on platform 12. XY stage 14 is a moving stage. XY stage 14 comprises an x-axis motor assembly and y-axis motor assembly. XY stage 14 controls the two dimensional movement (x- and y-axis movement) of the materials on the stage. The bonding region can thus be selectively controlled by moving XY stage 14. Vertical or z-axis movement is controlled by piston 16. In one embodiment, piston 16 may also be a z-axis stepper table.

Base substrate 52 is located on XY stage 14. Cover substrate 52 is loaded on and aligned with base substrate 52 prior to laser selective bonding. Piston 16 moves platform 12 towards the quartz loading plate 26. When piston 16 moves platform 12 adjacent to quartz loading plate 26, quartz loading plate 26 creates interface or contact pressure between cover substrate 50 and base substrate 52, at surface contact 54. The magnitude of the pressure applied by quartz loading plate 26 can be controlled by the amount of movement of piston 16.

A laser 20 is also located on vibration-free table 10. Laser 20 can be implemented as a dye laser, gas laser, semiconductor laser, or solid state laser. In FIG. 1, a laser beam, from laser 20 is directed through refractive and diffractive laser optics 24. Laser optics 24 direct, guide and focus the laser beam onto quartz loading plate 26. The laser beam passes through quartz loading plate 26 and through cover substrate 50, selectively bonding base substrate 52 to cover substrate 50 at surface contact 54, as described in detail in FIG. 5.

Using the apparatus described in FIG. 1, the laser bonding technique can be performed in an ordinary room environment. Vacuum conditions or a clean room environment are not needed for the laser selective bonding technique. Additionally, high temperatures required for most other types of bonding techniques are not needed. However, the apparatus in FIG. 1 has the ability to control the temperature inside precision vibration-free table 10.

Moreover, the laser-based set-up illustrated in FIG. 1 is consistent with the set-up of common semiconductor fabrication, for example, the Complementary Metal Oxide Semiconductor (CMOS) process. Therefore, the new bonding technique can be performed during the fabrication stage which avoids realignment of cover substrate 50 and base substrate 52 bonding locations in the packaging stages. Thus, laser selective bonding reduces the cost of the fabrication process.

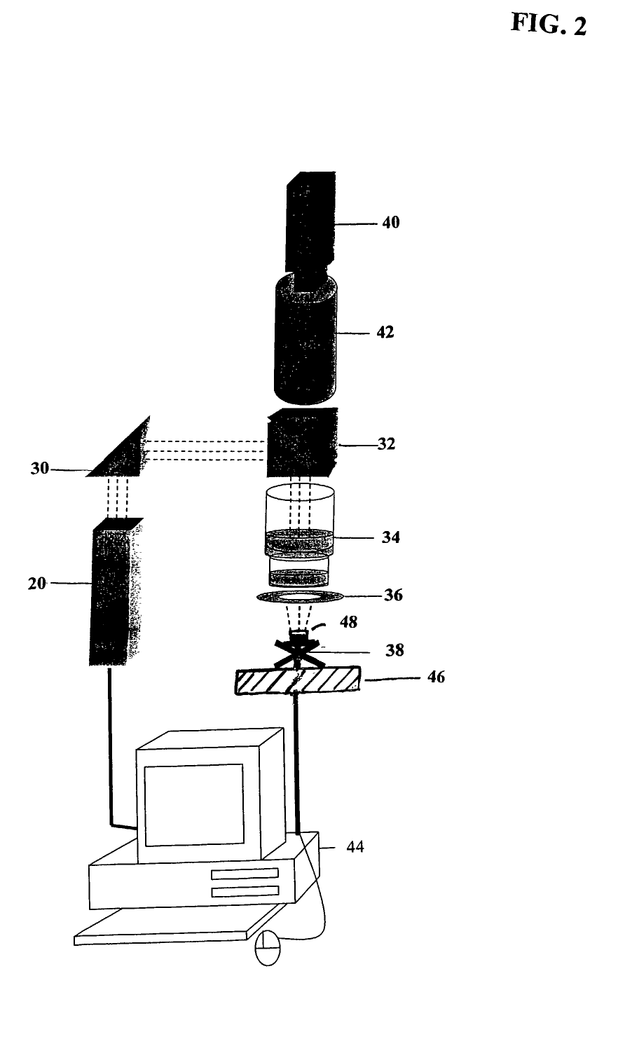

FIG. 2 illustrates an alternate embodiment of an apparatus used for laser selective bonding. FIG. 2 comprises laser 20, right-angle prism 30, beam splitter 32, microscope 34, illumination ring 36, and XYZ stage 38 which is located on platform 46 and is movable in three directions under control of computer 44. The apparatus is located on a vibration-free table (not shown).

Laser 20 is a Spectra Physics, GCR130-10 model, 450 mJ pulsed, high-powered Nd:YAG laser. Laser 20 achieves power concentrations on the order of tens of megawatts in 2 nanosecond (ns) and 8 ns pulses. Laser 20 has operating wavelengths that include the fundamental wavelength of 1.604 μm, (Infrared or IR), and its second and third harmonics. The second harmonic is 532 nm (Visible or Green), and the third harmonic is 266 nm (Ultraviolet or UV). Laser 20 also has the capability of producing a long pulse of 125 μm. Personal computer 44 controls and programs the laser with a computer-integrated manufacturing (CIM-2) programmable interface module through the serial port.

Right-angle prism 30 and beam splitter 32 are refractive and diffractive optics for beam guidance and focusing. Microscope 34 is a Mitutoyo objective microscope capable of sub-micron resolution. Microscope 34 allows a laser beam to be precisely focused on micrometer and nanometer targets. Illumination ring 36 provides for illumination, in the form of ring lighting, of XYZ stage 38. XYZ stage 38 rests on platform 46. Substrates 48, comprising a cover substrate and a base substrate are located on XYZ stage 38. XYZ stage 38 moves substrates 48 during the selective bonding process.

XYZ stage 38 is a prevision Compumotor XYZ stage capable of sub-micron positioning of micrometer and nanometer targets on XYZ stage 38. As in FIG. 1, XYZ stage 38 comprises an x-axis assembly motor, a y-axis assembly motor, and a piston or z-axis stepper table, all controlled by a personal computer 44. Personal computer 44 controls XYZ stage 38 with three programmable indexers.

Additionally, the laser system may comprise a charge-coupled device (CCD) camera 40 and a TV tube 42. CCD camera 40 and TV tube 42, in combination with illumination ring 36, allow a user to view the laser selective bonding process.

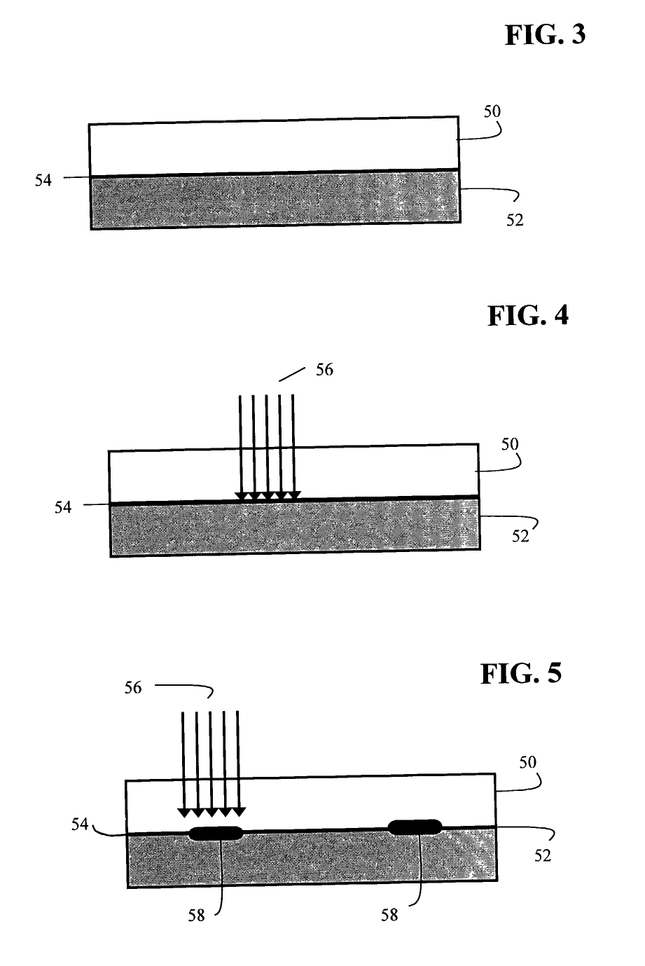

FIG. 3 illustrates cover substrate 50 and base substrate 52 prior to laser selective bonding. Cover substrate 50 is disposed adjacent to or brought into contact with base substrate 52. In one embodiment, cover substrate 50 is positioned on top of base substrate 52, relative to the directional location of the source of the laser beam. Cover substrate 50 and base substrate 52 are disposed adjacent to each other at surface contact 54.

Cover substrate 50 is made with a transparent material. Transparent material is defined as that material which has the property of transmitting rays of electromagnetic waves with a specific spectrum range. For example, if material is defined as transparent in the visible light region of the spectrum, the human eye should see through the material distinctly. Normally, if light or an electromagnetic wave transmits through a transparent material or medium, a portion of the light can be absorbed by the medium, as well as a portion of the light reflected from the medium's surface.

Transparency can also defined by a material's or medium's “transmission factor” or “transmission.” Transmission factor is defined as the ratio of the transmitted flux of the electromagnetic wave to the incident flux for the medium per unit of thickness. Transmission, on the other hand, represents the ratio of the transmitted flux of the electromagnetic wave for a medium with a specific thickness.

Therefore, both the medium's transmission factor and transmission are determined by the characteristics of the medium itself and the wavelength of the electromagnetic wave being transmitted. According to one embodiment, transparency is defined as materials with transmission greater than or equal to about ninety percent.

For example, transmission of about ninety percent could be achieved using Coming Pyrex 7740, at a thickness of 2 mm, and an electromagnetic wave with a wavelength between 200 nm and 2.2 μm. To increase transmission of Coming Pyrex 7740, the thickness of the transparent material can be decreased. Numerous optical materials have transmission values higher than ninety percent in similar wavelength ranges. For example, the transmission value of fused silica glass is greater than ninety-five percent at wavelengths between 250 nm to 1.1 μm.

One embodiment envisions that cover substrate 50 comprises numerous materials which at given wavelengths have transmission values greater than ninety percent. Materials that may be used include, but are not limited to, soda-lime glass (SK7), fused silica glass, borosilicate glass, quartz, glass ceramic, titanium silicate glass, aluminosilicate glass, and float glass.

Base substrate 52 is an opaque substrate. In contrast with cover substrate 50, which transmits a large portion of electromagnetic waves, an opaque substrate has a very low transmission factor or transmission. Opaque substrates that may be used are aluminum, steel, silicon nitride, and polysilicon. Therefore, an opaque substrate absorbs, rather than propagates, electromagnetic waves, causing the surface of base substrate 52 to melt, in the case of thermal diffusion, or evaporate, in the case of ablation, once base substrate 52 reaches its phase transition temperature.

FIG. 4 illustrates laser beam or electromagnetic waves 56 being transmitted through cover substrate 50 to base substrate 52. Electromagnetic waves 56 includes electromagnetic waves produced by a laser beam, radiation, or other light source. In most cases, electromagnetic waves 56 are emitted by electrons in the atoms of a light source. The light emerging from a laser, in the form of laser beam, is a coherent combination of electromagnetic waves 56, in that all light waves from the atoms of the laser are in phase at a specific wavelength. The specific wavelength emitted by the laser is dependent of the source of the atoms. In one embodiment, the electromagnetic waves 56 are in the form of a laser beam that can have wavelengths ranging from infrared to ultraviolet wavelengths.

The wavelength of electromagnetic waves 56 is largely determined by the material used for cover substrate 50. The wavelength of electromagnetic waves 56 is determined by the thickness and transmission properties of cover substrate 50, in order to maximize the transmission value of cover substrate 50. For example, if cover substrate 50 is 2 mm thick fused silica glass, and electromagnetic waves 56 have a wavelength between 250 μm and 1.1 μm, the transmission value of cover substrate 50 will exceed ninety percent. Therefore, during the laser selective bonding process, as illustrated in FIG. 4, electromagnetic waves 56 are transmitted through cover substrate 50 to base substrate 52 at surface contact 54 where a surface of base substrate 52 is disposed adjacent to a surface of cover substrate 50.

FIG. 5 illustrates one embodiment of a method of making a sealed microchannel structure. In FIG. 5, electromagnetic waves 56 have been transmitted through cover substrate 50 to base substrate 52. Electromagnetic waves 56 become incident to base substrate 52 at the surface of base substrate 52. The transmitted energy from electromagnetic waves 56 is then absorbed by base substrate 52. More specifically, a small portion of the surface layer of base substrate 52, disposed adjacent to cover substrate 50, absorbs the energy transmitted, in the form of electromagnetic waves 56, through cover substrate 50.

The high-density energy of electromagnetic waves 56 melts, in the case of thermal diffusion, or evaporates, in the case of ablation, a small surface portion of base substrate 52 in a controlled manner, creating sealed microchannel 58. Sealed microchannel 58 is a fusion joint between cover substrate 50 and base substrate 52. Sealed microchannel 58 firmly bonds cover substrate 50 to base substrate 52.

In one embodiment, electromagnetic waves 56 are transmitted by a laser in the form of a laser beam. Electromagnetic waves 56 can have two basic types of laser interaction with base substrate 52 in creating sealed microchannel 58. In each type of interaction, the laser transmits electromagnetic waves 56 through cover substrate 50 and heats base substrate 52 to a phase transition temperature of base substrate 52.

The first type of laser interaction is known as ablation, vaporization, or evaporation. In ablation, the laser photo energy of electromagnetic waves 56 is high enough to break atomics bonds in the material comprising base substrate 52, dissolving or evaporating a portion of base substrate 52. More specifically, ablation occurs when the laser energy of electromagnetic waves 56 is greater than the bonding energy of base substrate 52 and the laser pulse duration of electromagnetic waves 56 is shorter than the thermal-diffusion time. For most materials, thermal-diffusion time is greater than 10 picoseconds (ps). Thus, laser pulse duration for ablation to occur is generally less than 10 ps.

A laser having a laser beam with a pulse duration of less than 10 ps is generally more expensive to use than lasers with a longer pulse duration. Additionally, lasers with the capacity to produce energy greater than most materials' bonding energy are also expensive to build and use.

The second type of laser interaction is thermal diffusion or melting. In thermal diffusion, the heat deposited onto base substrate 52 by electromagnetic waves 56, diffuses away from the point on base substrate 52 interacting with electromagnetic waves 56 during the laser pulse duration. Normally, for most materials used as base substrate 52, the laser pulse duration needed to accomplish thermal diffusion or melting of base substrate 52 is greater than 10 ps, but still less than 125 microseconds (μs). Additionally, laser beam 56 has an energy less than the bonding energy of base substrate 52.

Therefore, in one embodiment, electromagnetic waves 56 have an energy less than the bonding energy of base substrate 52 and the laser is pulsed between 10 ps and 125 μs. Thus, the laser is operating in thermal-diffusion mode. In thermal diffusion mode, electromagnetic waves 56 melt a small, thin spot of the surface layer of base substrate 52 that is disposed adjacent to cover substrate 50 at surface contact 54.

More specifically, electromagnetic waves 56 act a heat source and target a portion of base substrate 52. The surface region of base substrate 52 is heated for more than 10 ps and ultimately reaches its phase-transition temperature, at which time, the surface region of base substrate 52 begins to melt. Once base substrate 52 begins to melt, fusion welding occurs between the melting surface portion of base substrate 52 and cover substrate 50 at surface contact 54.

Standard fusion welding techniques use heat to melt two surfaces together to create surface joints. Thus, in standard fusion welding, both surfaces are directly exposed to the heat source. However, in laser selective bonding, the surfaces of the materials do not have to be directly exposed to the heat source, in one example, the laser beam. Electromagnetic waves 56 are capable of penetrating or transmitting through cover substrate 50 and melting the surface layer of base substrate 52, underneath cover substrate 50.

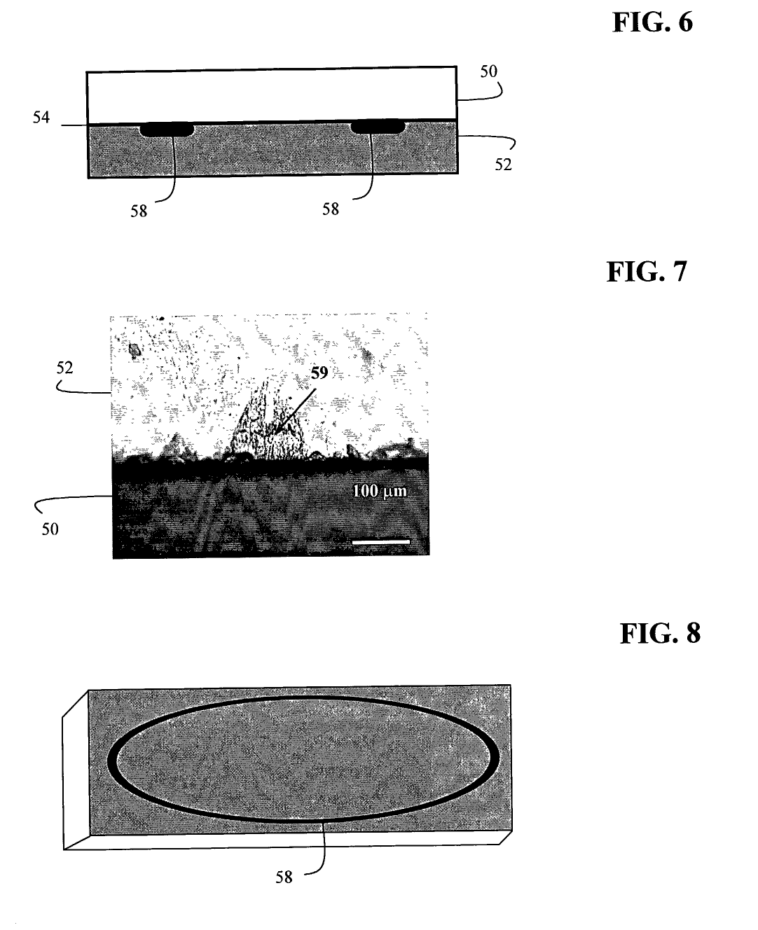

FIG. 6 illustrates a cross-sectional view of sealed mircochannel structure 58 following thermal diffusion. After base substrate 52 has been melted, base substrate 52 coalesces or fuses with cover substrate 50 at the fusion welding region. Coalescing or fusion bonding occurs when the two substrates merge, amalgamate, join together, or form a union. Once the coalesced region is solidified, a bonding or weld is formed between cover substrate 50 and base substrate 52, creating “interface” joints or bonds between the substrates. Thus, sealed microchannel structure 58 is formed by a submerged interface bond between the layered substrates.

FIG. 7 is a micrograph of a silicon-to-glass bond created by laser selective bonding. In FIG. 7, the base substrate 52 or silicon, is shown on the top. Cover substrate 50, or Corning Pyrex 7740 glass, is shown on the bottom of the micrograph. As FIG. 7 illustrates, base substrate 52, in this example, silicon, underwent thermal diffusion, melting a portion of base substrate 52, creating melt pool 59. Once melted, base substrate 52 coalesced with cover substrate 50, in this example, forming a silicon-to-glass bond or joint between base substrate 52 and cover substrate 50. Thus, melt pool 59 is a submerged interface bond.

FIG. 8 illustrates a three-dimensional view of sealed microchannel structure 58. In FIG. 8, laser selective bonding has created a seal around the perimeter of the substrates, fusing the substrates together along the weld.

The laser selective bonding technique can be used to join or bond a large variety of metallic and non-metallic (e.g. ceramic and polymer) materials. Special roughness of the substrates is not required to bond the surfaces. In contrast to conventional bonding techniques, bonding need not be created over the entire area of the substrates, but the substrates can be selectively bonded at any desired point or in any pattern.

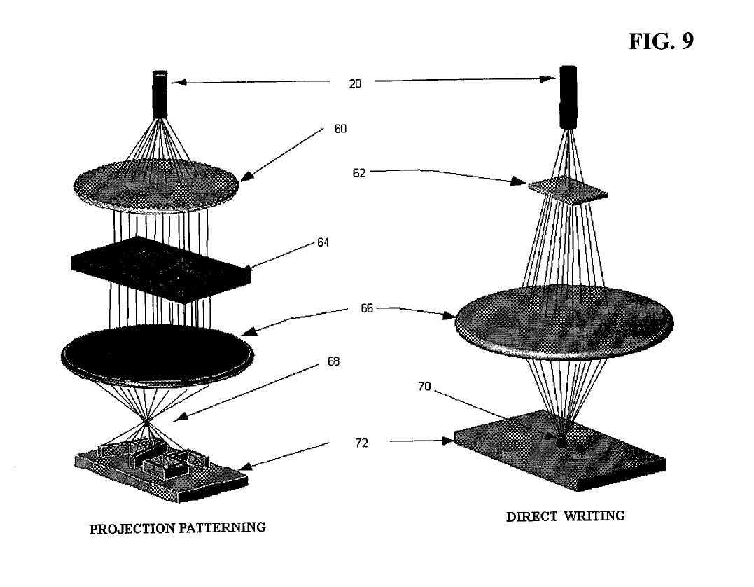

FIG. 9 illustrates two alternate embodiments of sealed microchannels structures. The first embodiment is projection patterning or mask projection process. Projection patterning is also known as the lithographic approach. The mask projection process uses a laser to backlight mask and project the mask image onto the substrate. In projection patterning, laser 20 produces a laser beam which is directed through condenser 60. Condenser 60 gather as much of the laser light from the source as possible and directs it though projection mask 64. Projection mask 64 comprises a patterned filter.

In FIG. 9, the pattern of projection mask 64 is SV. After the laser beams passes through projection mask 64, the laser beam then passes through objective lens 66. By appropriate optics, objective lens 66 inverts the image or pattern on projection mask 64 at cross over point 68 and after cross over projects the electromagnetic waves of the laser beam, in a mirror image of the pattern, through the cover substrate onto the surface of the base substrate. Cross over point 68 is adjusted to create the required or appropriate size of the pattern for the substrate. The base substrate and cover substrate are selectively bonded in the inverted pattern, in this example, AS.

The mask projection process allows production of bonding features over a large surface area at one time. Mask projection is well-suited to high-volume production applications of a fixed bonding pattern. Additionally, because relatively large surface areas are exposed simultaneously, a high-energy laser source should be used.

A second embodiment is direct writing. The direct writing approach uses a similar but smaller source of electromagnetic waves can be used. The direct writing approach focuses the entire laser beam onto the substrate surface and control the movement of the substrate under the focused beam providing the ability to create varied writing or patterns on each individual substrate. In direct writing, laser 20 produces a laser beam which is first directed through modulator 62. Modulator 62 helps maintain the same frequency of the laser beam. Modulator 62 then directs the laser beam through objective lens 66. In this embodiment, objective lens 66 is a converging objective lens which focuses the laser onto a small spot which will be used for writing the bonding lines onto the substrate. Therefore, objective lens 66 directs the electromagnetic waves of the laser beam through the cover substrate and converges the electromagnetic waves onto a single convergence point 70 on the base substrate.

Direct writing allows the user to direct electromagnetic waves in a manner that selectively bonds the base substrate and cover substrate in one or more points, in a separated or contiguous manner, along the base substrate. Computer control of the substrate movement, as shown in FIG. 2, allows direct production of CAD-generated bonding features and rapid pattern changes. Direct writing also allows for free-form writing in the substrate. The direct writing approach is advantageous for small batch production, prototyping, and customization.

Various embodiments of the invention are described above in the Drawings and Description of Various Embodiments. While these descriptions directly describe the above embodiments, it is understood that those skilled in the art may conceive modifications and/or variations to the specific embodiments shown and described herein. Any such modifications or variations that fall within the purview of this description are intended to be included therein as well. Unless specifically noted, it is the intention of the inventor that the words and phrases in the specification and claims be given the ordinary and accustomed meanings to those of ordinary skill in the applicable art(s). The foregoing description of a preferred embodiment and best mode of the invention known to the applicant at the time of filing the application has been presented and is intended for the purposes of illustration and description. It is not intended to be exhaustive or to limit the invention to the precise form disclosed, and many modifications and variations are possible in the light of the above teachings. The embodiment was chosen and described in order to best explain the principles of the invention and its practical application and to enable others skilled in the art to best utilize the invention in various embodiments and with various modifications as are suited to the particular use contemplated. Therefore, it is intended that the invention not be limited to the particular embodiments disclosed for carrying out this invention, but that the invention will include all embodiments falling within the scope of the appended claims.

What is claimed is:

1. A microchannel structure, comprising:
a base substrate; and
a cover substrate disposed adjacent to the base substrate, wherein a surface of the base substrate is adapted for heating to a phase transition temperature by transmitting electromagnetic waves through the cover substrate to the surface of the base substrate to coalesce the base substrate to the cover substrate.

2. The microchannel structure of claim 1, wherein the base substrate comprises opaque material.

3. The microchannel structure of claim 1, wherein the cover substrate comprises transparent material.

4. The microchannel structure of claim 3, wherein the transparent material has a transmission of at least ninety percent.

5. The microchannel structure of claim 1, wherein the electromagnetic waves are transmitted by a laser beam.

6. The microchannel structure of claim 1, wherein the electromagnetic waves are transmitted by radiation.

7. The microchannel structure of claim 1, wherein the base substrate is coalesced to the cover substrate by direct writing.

8. The microchannel structure of claim 1, wherein the base substrate is coalesced to the cover substrate by projection patterning.

9. The microchannel structure of claim 1, wherein the base substrate melts at the phase transition temperature.

10. The microchannel structure of claim 1, wherein the surface of the base substrate is heated where the electromagnetic waves become incident to the base substrate.

11. A method of making a microchannel structure, comprising:
transmitting electromagnetic waves through a cover substrate to a base substrate disposed adjacent to the cover substrate; and
heating a portion of the base substrate with the electromagnetic waves until the portion of the base substrate incident to the electromagnetic waves reaches a phase transition temperature and coalesces with a portion of the cover substrate.

12. The method in claim 11, wherein the cover substrate comprises transparent material.

13. The method in claim 11, wherein the base substrate comprises opaque material.

14. The method of claim 11, wherein the electromagnetic waves are transmitted by a laser beam.

15. The method of claim 11, wherein the electromagnetic waves are transmitted by radiation.

16. The method of claim 11, wherein the base substrate melts at the phase transition temperature.

17. An apparatus for making a microchannel structure, comprising:
a base substrate;
a cover substrate disposed adjacent to the base substrate; and
a laser positioned to transmit a laser beam through the cover substrate and heat a surface of the base substrate.

18. The apparatus in claim 17, wherein the base substrate comprises opaque material.

19. The apparatus in claim 17, wherein the cover substrate comprises transparent material.

20. The apparatus of claim 17, further comprising an XYZ stage, adapted to move the base substrate.

21. The apparatus of claim 17, wherein the laser is adapted to melt the base substrate.

22. The apparatus of claim 17, further comprising a quartz loading plate.

23. A microchannel structure, comprising:
a base substrate; and
a cover substrate disposed adjacent to the base substrate, wherein a portion of the base substrate is heated to a phase transition temperature by electromagnetic waves transmitted through the cover substrate to join the portion of the base substrate to a portion of the cover substrate.

24. The microchannel structure in claim 23, wherein the electromagnetic waves form a bond between the base substrate and cover substrate in a pattern, sealing the base substrate and the cover substrate.

25. The microchannel structure in claim 23, wherein the electromagnetic waves fuse the base substrate and the cover substrate by thermal diffusion.
